(19) United States
(12) Patent Application Publication
(10) Pub. No.: US 2023/0244837 A1
(43) Pub. Date: Aug. 3, 2023

(54) ATTRIBUTE BASED MODELLING

(71) Applicant: ACCENTURE GLOBAL SOLUTIONS LIMITED, Dublin (IE)

(72) Inventors: Antonios KÜHN, Athens (GR); Nikolaos SOUZAS, Antibes (FR)

(73) Assignee: ACCENTURE GLOBAL SOLUTIONS LIMITED, Dublin (IE)

(21) Appl. No.: 17/695,596

(22) Filed: Mar. 15, 2022

(30) Foreign Application Priority Data
Jan. 31, 2022 (EP) 22386005.7

(51) Int. Cl. G06F 30/27; G06Q 30/02

(52) U.S. Cl. CPC G06F 30/27; G06Q 30/0201

(57) ABSTRACT

Systems and methods for attribute-based modelling are disclosed. A system includes an attribute-based decomposition engine, which when executed using a processor, causes the engine to retrieve one or more product attributes associated with each of a set of products, an importance of the product attributes being determined based on the product sales data, product data, product parameters, and financial data associated with product. The attribute-based decomposition engine using the processor establishes, for a set of products, a relationship between a retrieved one or more product attributes and product sales associated with product, based on implementation of a non-parametric machine learning (ML) modeling on a data model. The attribute-based decomposition engine quantifies contribution of each product attribute on product sales based on an established relationship and a game theoretic framework. The attribute-based decomposition engine using the processor estimates demand transferability among a set of products based on the determined weights of the respective product attributes.

### BACKGROUND

Generally, consumers make purchases based on occasions. Consumers may shop for the same products in different ways on different shopping occasions based on respective consumer needs. For example, for a particular product, in terms of pack size selection, channel preference and price sensitivity, a monthly stock-up purchase may be different from a purchase for immediate consumption or a purchase to use during travel. Retailers/manufacturers may need to have a good understanding about product attributes to realize the value of the products. For example, when consumers are in a super market, what prompts a consumer to purchase product ‘A’ vs. product ‘B’? Retailers/manufacturers may need to understand the product characteristics to maximize sales and consumers may need to understand the product characteristics in supermarkets to buy products based on requirement. The retailers/manufacturers may need to understand each product at, for example, supermarkets, hypermarkets, grocery store and so on, to help positioning products and to create the optimal mixture of products and characteristics while defining the assortment for each channel of the products. The optimal mixture of products and characteristics which may be available to the consumer may maximize sales, market sell and so on, to the retailers/manufacturers.

Further, retailers/manufacturers and/or brands may need to ensure that they provide consumers an appropriate selection of products that meet all the consumer needs at the price points the consumers may be willing to pay. The appropriate selection of products that meet all the consumer needs may be achieved using an analytical technique or methodology such as a Price Pack Architecture (PPA). The PPA may leverage consumer willingness to pay for certain features and benefits. Some of the questions that brands may need to answer in order to determine the optimal PPA may include, for example, what are consumers willing to pay for existing product features? For what product features or benefits are consumers willing to pay a significant premium? Will consumers pay a high-enough premium for convenience offered by smaller pack sizes? Which segment or profile of my consumers find new products most appealing? How should retailers/manufacturers position new products to maximize the overall brand portfolio sales? How will my new products compete with my existing product range? How much will new products cannibalize my current portfolio sales? In addition, the brands may need to be cautious about, for example, properly distributing the products in assortment across logical price point groupings, maintaining consistent brand and feature premiums across the category, finding ways to adjust prices relative to one another to improve overall profitability, providing consumers with a viable selection of products that meet their needs at the price they are willing to pay, both through price adjustments to existing products and the introduction of new product. The product mix/product assortment may include a number of products that a company may offer to its shoppers/consumers. For example, a company might sell multiple lines of products, with the product lines being fairly similar, such as, for example, toothpaste, toothbrush, or mouthwash, and other such products.

Conventional systems may not provide automated and scalable systems to estimate the importance (i.e., weights) of the product characteristics (i.e., attributes), which may be used in order to estimate the demand transferability among products, when changes are applied to the portfolio/product mix. Conventional systems may also not unravel the relationship of product attributes on product non-promotional sales to quantify the contribution each product attribute brings to the prediction of sales. Further, conventional systems may not utilize the attribute importance of each product, calculate the uniqueness of each product, and estimate the demand transferability by quantifying the potential volume to be transferred to other products, or potentially lost from the product category for each hypothetical scenario of portfolio reduction/change/increase.

Therefore, conventional systems may be unable to provide a data driven decision approach based on the PPA product assortment mixture, and a product attribute decomposition method, to help retailers/manufacturers/brands determine the right PPA for driving product portfolio growth and enhance the overall product value proposition to the consumers.

### SUMMARY

An embodiment of present disclosure includes a system comprising an attribute-based decomposition engine. The attribute-based decomposition engine, when executed using a processor, may cause the engine to retrieve one or more product attributes associated with each of a set of products, an importance of the one or more product attributes being determined based on the product sales data, product data, product parameters, and financial data associated with the product. The attribute-based decomposition engine using the processor may establish for the set of products a relationship between the retrieved one or more product attributes and product sales associated with the product, based on the implementation of non-parametric machine learning (ML) modeling on a data model. Further, the attribute-based decomposition engine using the processor may quantify a contribution of each product attribute on the product sales, based on the established relationship and a game theoretic framework. The contribution of each product attribute on the product sales is quantified to determine weights of the respective product attributes. Furthermore, the attribute-based decomposition engine using the processor may estimate demand transferability among the set of products based on the determined weights of the respective product attributes.

Another embodiment of the present disclosure may include a method for attribute-based modelling. The method may include retrieving one or more product attributes associated with each of a set of products, an importance of the one or more product attributes being determined based on the product sales data, product data, product parameters, and financial data associated with the product. The method may include establishing for the set of products a relationship between the retrieved one or more product attributes and product sales associated with the product, based on the implementation of non-parametric machine learning (ML) modeling on a data model. Further, the method may include quantifying a contribution of each product attribute on the product sales, based on the established relationship and a game theoretic framework. The contribution of each product attribute on the product sales is quantified to determine weights of the respective product attributes. Furthermore, the method may include estimating demand transferability among the set of products based on the determined weights of the respective product attributes.

Yet another embodiment of the present disclosure may include a non-transitory computer readable medium comprising machine executable instructions that may be executable by a processor to receive an input data corresponding to a programming language. The processor may retrieve one or more product attributes associated with each of a set of products, an importance of the one or more product attributes being determined based on the product sales data, product data, product parameters, and financial data associated with the product. The processor may establish for the set of products a relationship between the retrieved one or more product attributes and product sales associated with the product, based on the implementation of non-parametric machine learning (ML) modeling on a data model. Further, the processor may quantify a contribution of each product attribute on the product sales, based on the established relationship and a game theoretic framework. The contribution of each product attribute on the product sales is quantified to determine weights of the respective one or more product attributes. Furthermore, the processor may estimate demand transferability among the set of products based on the determined weights of the respective product attributes.

### BRIEF DESCRIPTION OF DRAWINGS

FIG. 1 illustrates an exemplary block diagram representation of a system for attribute-based modelling, according to an example embodiment of the present disclosure.

FIG. 2 illustrates an exemplary block diagram depicting components of the system of FIG. 1, according to an example embodiment of the present disclosure.

FIG. 3A illustrates an exemplary flow diagram representation depicting an outcome of the system, according to an example embodiment of the present disclosure.

FIG. 3B illustrates an exemplary block diagram representation of logical components of a pre-configured azure tech stack, according to an example embodiment of the present disclosure.

FIG. 3C illustrates an exemplary block diagram representation of Azure architecture, according to an example embodiment of the present disclosure.

FIG. 3D illustrates an exemplary block diagram representation of an Azure analytical model, according to an example embodiment of the present disclosure.

FIG. 3E illustrates an example schematic diagram representation of data elements including external and internal sources, according to an example embodiment of the present disclosure

FIG. 3F illustrates an example flow diagram representation depicting a pre-processing and harmonization of raw data, according to an example embodiment of the present disclosure.

FIG. 3G illustrates example flow diagram representation depicting an atomic data model in a data vault schema, according to an example embodiment of the present disclosure.

FIG. 3H illustrates an exemplary flow diagram representation depicting working of decision trees, according to an example embodiment of the present disclosure.

FIG. 3I illustrates exemplary flow diagram representation depicting working of a ShaPley Additive exPlanations (SHAP), according to an example embodiment of the present disclosure.

FIG. 3J illustrates a graph diagram of attribute-based modelling outputs, according to an example embodiment of the present disclosure.

FIG. 3K illustrates a schematic diagram representation of testing and validation of attribute-based modelling, according to an example embodiment of the present disclosure.

FIG. 4 illustrates a hardware platform for implementation of the disclosed system, according to an example embodiment of the present disclosure.

FIG. 5 illustrates a flow diagram representation depicting method of attribute-based modelling, according to an example embodiment of the present disclosure.

### DETAILED DESCRIPTION

For simplicity and illustrative purposes, the present disclosure is described by referring mainly to examples thereof. The examples of the present disclosure described herein may be used together in different combinations. In the following description, details are set forth in order to provide an understanding of the present disclosure. It will be readily apparent, however, that the present disclosure may be practiced without limitation to all these details. Also, throughout the present disclosure, the terms “a” and “an” are intended to denote at least one of particular element. The terms “a” and “an” may also denote more than one of a particular elements. As used herein, the term “includes” means includes but not limited to, the term “including” means including but not limited to. The term “based on” means based at least in part on, the term “based upon” means based at least in part upon, and the term “such as” means such as but not limited to. The term “relevant” means closely connected or appropriate to what is being performed or considered.

Various embodiments describe providing a solution in the form of a system and a method for attribute-based modelling. The system includes an attribute-based decomposition engine. The attribute-based decomposition engine, when executed using a processor, may cause the engine to retrieve one or more product attributes associated with each of a set of products, an importance of the one or more product attributes being determined based on the product sales data, product data, product parameters, and financial data associated with the product. The attribute-based decomposition engine using the processor may establish for the set of products, a relationship between the retrieved product attributes and product sales associated with the product, based on the implementation of non-parametric machine learning (ML) modeling on a data model. Further, the attribute-based decomposition engine using the processor may quantify a contribution of each product attribute on the product sales, based on the established relationship and a game theoretic framework. The contribution of each product attribute on the product sales is quantified to determine weights of the respective product attributes. Furthermore, the attribute-based decomposition engine using the processor may estimate demand transferability among the set of products based on the determined weights of the respective product attributes. Transferability of demand is quantified from product to product and it is based on output of the attribute importance analysis. Statistical machine learning models are applied to the sales data in order to estimate the importance of the primary and secondary attributes. These are the key drivers for answering which products can be removed since their volume will be transferred to remaining products with similar characteristics if a product is deleted, or if a new product is added, or if attributes change. The deletion of the product may result in a transfer of demand to another product (or the loss of sales). For each business scenario (list, delist or price/pack attribute change) estimate which part of the volume sales associated with each attribute is potentially transferred to other products. The demand transferability factors for each product are considered to estimate the financial impacts while simulating different Price Pack Architecture (PPA) business scenarios.

Exemplary embodiments of the present disclosure have been described in the framework of a fully automated, scalable system to estimate the importance (weights) of the product characteristics (attributes). The estimation of the importance (weights) of the product characteristics (attributes) may be used in order to estimate the demand transferability among products, when changes are applied to a product portfolio mixture using technical components such as cloud architecture, flexible data modeling, Artificial Intelligence (AI) and game theory. Further, the embodiments of the present disclosure may include Machine Learning (ML) modeling using for example, random forests to unravel the relationship of product attributes on product non promotional sales, combined with game theory framework using SHapley Additive exPlanations (SHAP) values to quantify the contribution each product attribute brings to the prediction made by the ML model. Further, the embodiments of the present disclosure may utilize the attribute importance, calculate the uniqueness of each product and estimate a demand transferability by quantifying the potential volume to be transferred to other products, or potentially lost from the product category for each hypothetical scenarios of portfolio reduction/change/increase. Embodiments of the present disclosure may provide increased performance using non-parametric models which can substantially increase prediction accuracy, each product obtains a unique set of attribute importance instead of the global importance of the entire population. Embodiments of the present disclosure may be fully automated with no human intervention required to experiment in order to find the optimal ML model. The data pipelines and ML pipeline may be automated since the expected data sources are plugged in. Embodiments of the present disclosure may provide unlimited scale irrespective to data size, the system can scale to dozens of different markets, create thousands of different models across the product and categories and quantify attribute importance of millions of different product and attribute combinations. Embodiments of the present disclosure may provide thin grained results which includes attribute importance and demand transferability can be reported for every single product across any number of attributes

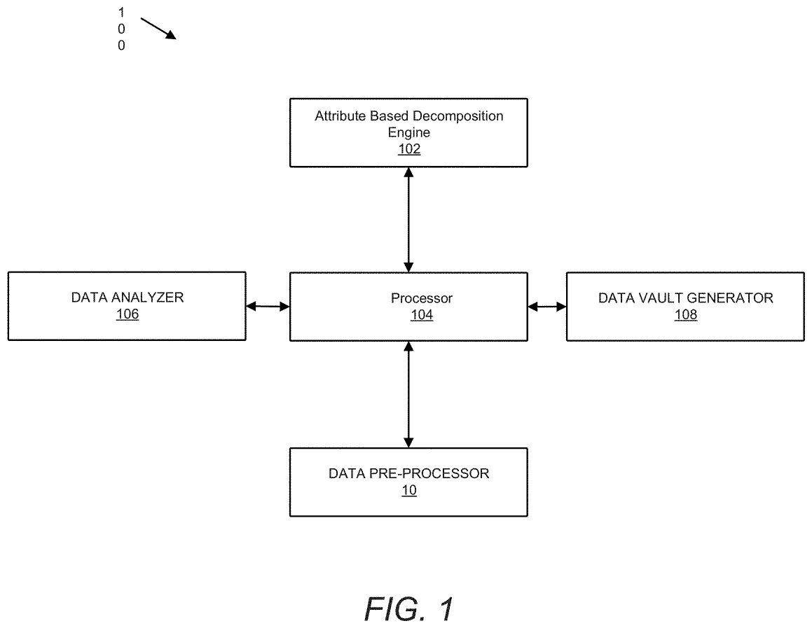

FIG. 1 illustrates an exemplary block diagram representation of a system 100 for attribute-based modelling, according to an example embodiment of the present disclosure. The system 100 may be implemented by way of a single device or a combination of multiple devices that may be operatively connected or networked together. The system 100 may be implemented in hardware or a suitable combination of hardware and software. The components of the system 100 may be implemented in core and/or back end of the overall architecture. The system 100 may include, a processor 104 including an attribute-based decomposition engine 102, a data analyzer 106, and a data pre-processor 110.

The data pre-processor 110 may generate an input dataset pertaining to a captured, sales, price, hierarchy, attributes, promotions, distribution, and so on, of one or more products. In an example embodiment, the captured trend may pertain to a pattern depicting at least one of a relative increase in demand of the product and a relative decrease in the demand of the product recorded over a definite period of time. The data pre-processor 110 may collect raw dataset from one or more sources (a raw data source) to generate the input dataset. The raw dataset may be collected from one or more raw data sources storing raw data pertaining to the one or more data elements. The raw data sources may include at least one of, an internal source and an external source. In an example embodiment, the internal source may include an organization associated with the product. For example, the internal source may include one or more entities that may be associated with at least one of product research, product manufacturing, product assembly, product marketing, entity associated with brand of the product and other entities indirectly or directly associated with the product. The external source may include an organization that collects information associated with at least one of a product survey, market research, competitor survey and product purchase trend pertaining to the product. In an example embodiment, the external source be a third-party entity that may be only concerned with accumulation/recording of a public survey for evaluating increase or decrease in demand/popularity of the product. In an example embodiment, the product may include, for example, consumer goods, services, experiences, convenience, shopping items, specialty goods, industrial goods and any other such product or service that may be purchased or may be available for vending. Several other types of products may also be included.

In an example embodiment, the raw dataset, collected from the one or more sources, may be pre-processed by extract, transform and load (ETL) mechanism to consolidate various datasets to store as the input dataset. Based on the processing of the input dataset, the data analyzer 106 may facilitate deriving automated insights. In an example embodiment, the automated insights may answer questions related to why a certain pattern is observed in the trend of product attributes. For example, the automated insights may provide the answer to a question such as what will be the impact if a product is delisted. As another example, the automated insights may provide an answer to a question such as which factors/drivers played a key role or impacted the sale of the product. Several other aspects may be explained based on the automated insights. In an example embodiment, the data analyzer 106 may include attribute-based models to understand sales performance in reference to the product attributes.

The data analyzer 106 may analyze the input dataset using data ingestion model. The data analyzer 106 may assess data quality to check and identify the gaps between data and ensure that all the data may be ready for processing. The data analyzer 106 may incorporate feedback from the business in case of any data gaps and transform any unstructured data into easily ingestible templates for the ease of data processing. Further, the data analyzer 106 may perform data validation based on sale matching and data quality validation. For example, sales matching includes matching primary sales from client database with third-party data, promo merging includes validating client's promotion calendar dated against Electronic Point of Sale (EPOS)/syndicated sales data, data quality may include treating data for missing values, outlier treatment and business inconsistencies. In an example embodiment, the system 100 may also include a data vault generator 108 to generate a data vault representation. The data vault representation may include relevant information pertaining to the product attributes. Each data point may store information corresponding to the one or more data elements associated with the product attributes. In an example embodiment, the data vault representation may be generated using at least one of the raw datasets and the input dataset. In an example embodiment, the data pre-processor 110 and the data analyzer 106 may be back-end components and the data vault generator 108 may be a core component.

The system 100 may be a hardware device including the processor 104 executing machine-readable program instructions to perform attribute-based modelling. Execution of the machine-readable program instructions by the processor 104 may enable the proposed system 100 to perform attribute-based modelling. The “hardware” may comprise a combination of discrete components, an integrated circuit, an application-specific integrated circuit, a field programmable gate array, a digital signal processor, or other suitable hardware. The “software” may comprise one or more objects, agents, threads, lines of code, subroutines, separate software applications, two or more lines of code or other suitable software structures operating in one or more software applications or on one or more processors. The processor 104 may include, for example, microprocessors, microcomputers, microcontrollers, digital signal processors, central processing units, state machines, logic circuits, and/or any devices that manipulate data or signals based on operational instructions. Among other capabilities, the processor 104 may fetch and execute computer-readable instructions in a memory operationally coupled with system 100 for performing tasks such as data processing, input/output processing, feature extraction, and/or any other functions. Any reference to a task in the present disclosure may refer to an operation being or that may be performed on data.

In an example embodiment, the attribute-based decomposition engine 102, when executed using the processor 104, may cause the engine to retrieve one or more product attributes associated with each of a set of products, an importance of the one or more product attributes being determined based on the product sales data, product data, product parameters, and financial data associated with the product. The attribute-based decomposition engine 102 using the processor 104 may establish for the set of products a relationship between the retrieved one or more product attributes and product sales associated with the product, based on the implementation of non-parametric machine learning (ML) modeling on a data model. In an embodiment, the non-parametric machine learning (ML) modeling may be based on Random Forest Algorithm. In an embodiment, the metadata associated with the non-parametric machine learning (ML) modeling may be selected from at least one of automated model hyper parameter tuning, a log of automated experiment iterations, ML model parameters, and valuation and performance metrics. In another aspect, the data model may be implemented based on a data agnostic and flexible data modeling technique to accommodate variation of external and internal data associated with the set of products. In another embodiment, the data model may be generated based on ingestion and storage of raw data associated with the set of products from a plurality of sources. The data model may be generated based on design and development of metadata for at least one of model versioning, model performance, model output, and action recommendation/simulation. Further, the data model may be generated based on building of the data model based on training using the ingested data and the developed metadata.

In an embodiment, the attribute-based decomposition engine 102 using the processor 104 may quantify a contribution of each product attribute on the product sales, based on the established relationship and a game theoretic framework. The contribution of each product attribute on the product sales is quantified to determine weights of the respective product attributes. In an embodiment, the game theoretic framework may be based on a SHapley Additive exPlanations (SHAP) approach that may process the relationship established by the machine learning (ML) modeling to enable the quantification of the contribution of each product attribute to the product sales. In an embodiment, the one or more product attributes are based on at least one of product sale/price data, product hierarchy, promotion and cost, target consumer, outlet location, product availability, outlet location attributes, competition, product distribution, target audience/market, and product parameters.

In an embodiment, the attribute-based decomposition engine 102 using the processor 104 may estimate demand transferability among the set of products based on the determined weights of the respective one or more product attributes. In an embodiment, the demand transferability may be indicative of a uniqueness of each product of the set of products, and quantification of potential volume to be transferred to other products or potentially lost from a given product category in instances of reduction, change, or increase in product portfolio. Transferability of demand is quantified from product to product and it is based on output of the attribute importance analysis. Statistical machine learning models are applied to the sales data in order to estimate the importance of the primary and secondary attributes. These are the key drivers for answering which products can be removed since their volume will be transferred to remaining products with similar characteristics if a product is deleted, or if a new product is added, or if attributes change. The deletion of the product may result in a transfer of demand to another product (or the loss of sales). For each business scenario (list, delist or price/pack attribute change) estimate which part of the volume sales associated with each attribute is potentially transferred to other products. The demand transferability factors for each product are considered to estimate the financial impacts while simulating different Price Pack Architecture (PPA) business scenarios.

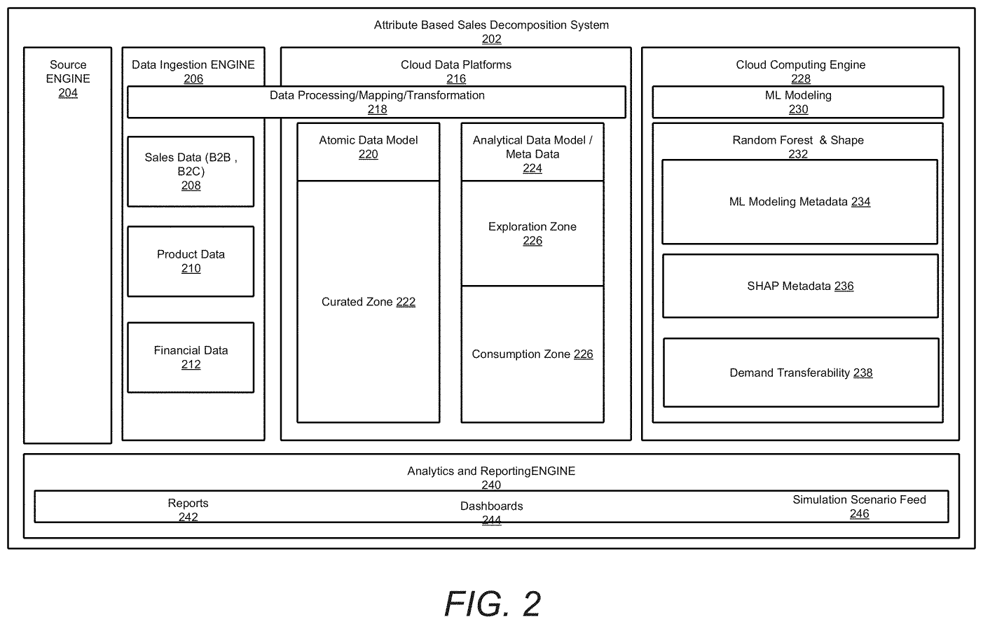

FIG. 2 illustrates an exemplary diagram depicting components of the system 100 of FIG. 1, according to an example embodiment of the present disclosure. The system 100 can be an attribute-based sales decomposition system 200. The attribute-based sales decomposition system 202 may include, a source engine 204, a data ingestion engine 206, cloud data platforms 216, a cloud computing engine 228, and an analytic and reporting engine 240. The data ingestion engine 206 may include, data processing/mapping/transformation 218, sales data 208 (Business to Business (B2B), Business to Customer (B2C)), product data 210, financial data 212. Further, the cloud data platforms 216 may include, the data processing/mapping/transformation 218, an atomic data model 220, analytical data model/meta data 224. The atomic data model 220 may include curated zone 222 in which data may be mapped, validated harmonized and transformed and store in unified data model following the data vault methodology principles. The data vault methodology may allow to consolidate internal/external data and scales the data for the global consumer goods companies that may take the data from one market to another market.

Further, the analytical data model/meta data 224 may include an exploration zone 226 feature engineering to create analytical data model 224, and a consumption zone 226 in which champion Machine Learning (ML) model may store for consumption and product metadata populated. The ML model may be non-parametric ML models to find the relationship between the product sales and the different attributes and sub buyers of a game theory in order to quantify the contribution of each attribute to the product sales performance of the product.

Further, the cloud computing engine 228 may include ML modeling 230, random forest and shape 232 which further includes ML modeling metadata 234, SHAP metadata 236, and a demand transferability 238. The ML modeling metadata 234 may be an automated model hyper parameter tuning log of automated experiment iterations champion model validation and performance metrics, the SHAP metadata 236 may be an attribute importance for all attribute arrays across all products, and the demand transferability 238 may be a product uniqueness index, a product transferable volume, and a product lost volume. The demand transferability 238 may be for example, when a product may be delisted or enlisted or change the attributes of an existing product, then what may be the incremental volume by the uniqueness of the new product characteristic, and so on. Further, the analytic and reporting engine 240 may include reports 242, dashboards 244, and a simulation scenario feeds 246. The attribute-based sales decomposition system 202 may automatically process any volume of sales and product data plus using Artificial intelligence (AI) to quantify the product attribute importance and demand transferability for millions of products and attribute combinations.

In an example embodiment, the product attribute may be recorded as master data for each product. As an example, the product attribute may include information pertaining to quantity of product vending/sales in a historical timeline, product hierarchy, product characteristics and other aspects pertaining to the product. The term “product hierarchy” may pertain to a representation of hierarchical relationships between various products and groups/categories of products at various hierarchy levels. For example, a higher hierarchy level offset may include the category “food” such that “frozen food” may be next lower hierarchy level to which a product, such as, for example, “pizza” may belong. The quantity of product vending/sales in a historical timeline may indicate an increase/decrease in the demand for the product over a definite time period. The “product characteristics” may pertain to a property of the product including at least one of physical characteristics, package, format, chemical characteristics, and other such aspects pertaining to the product.

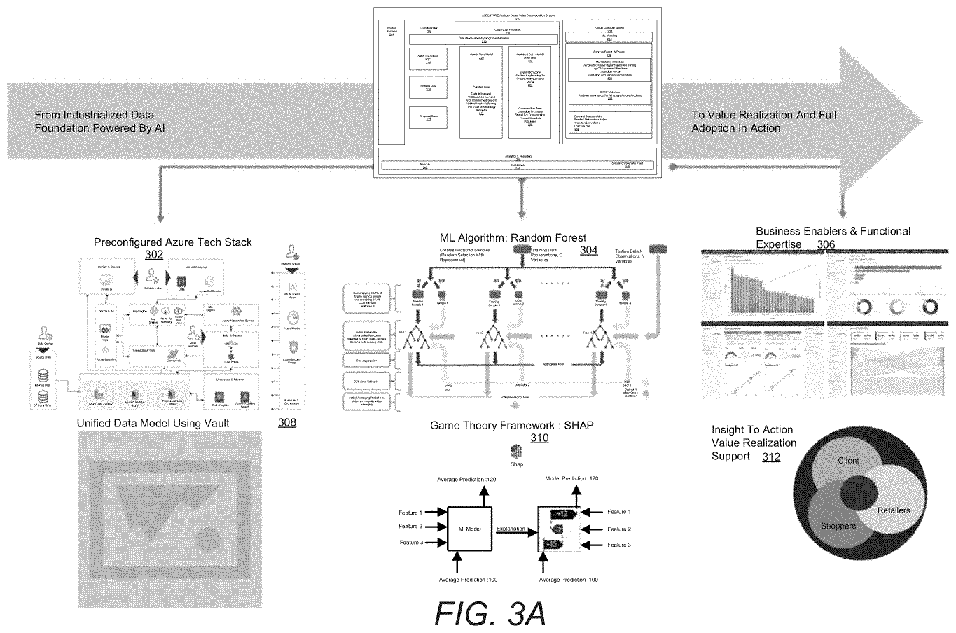

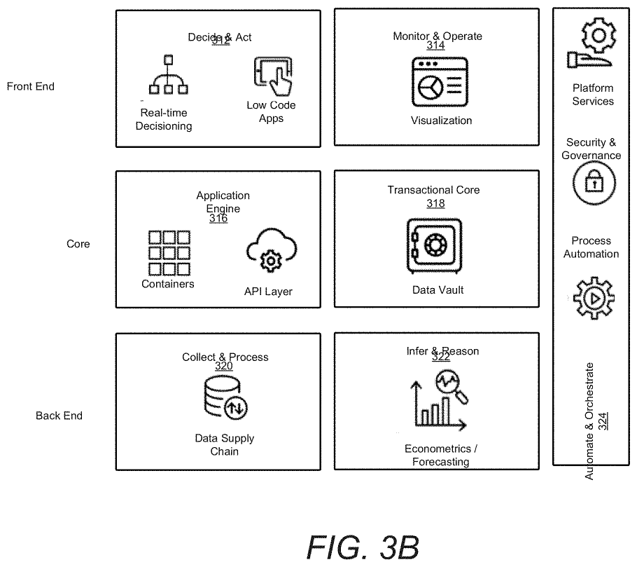

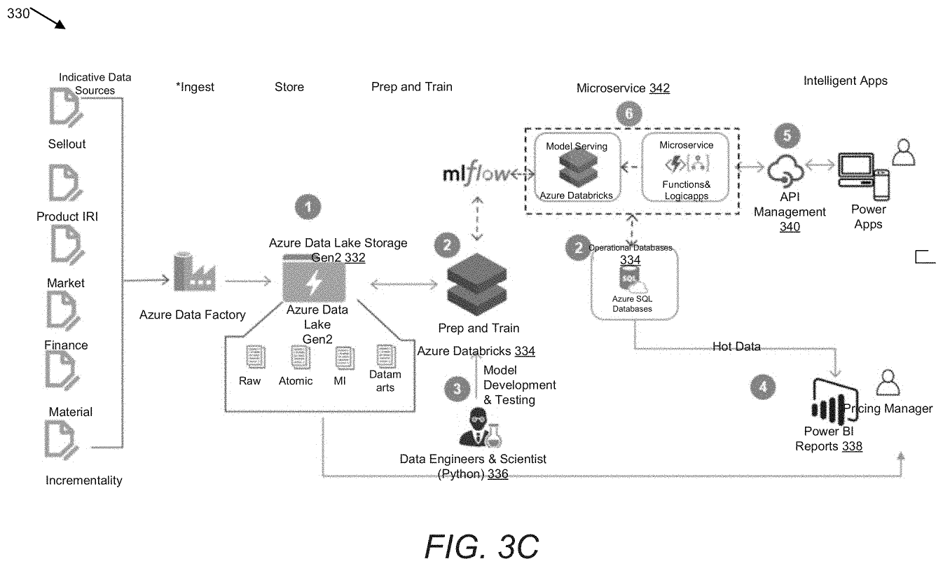

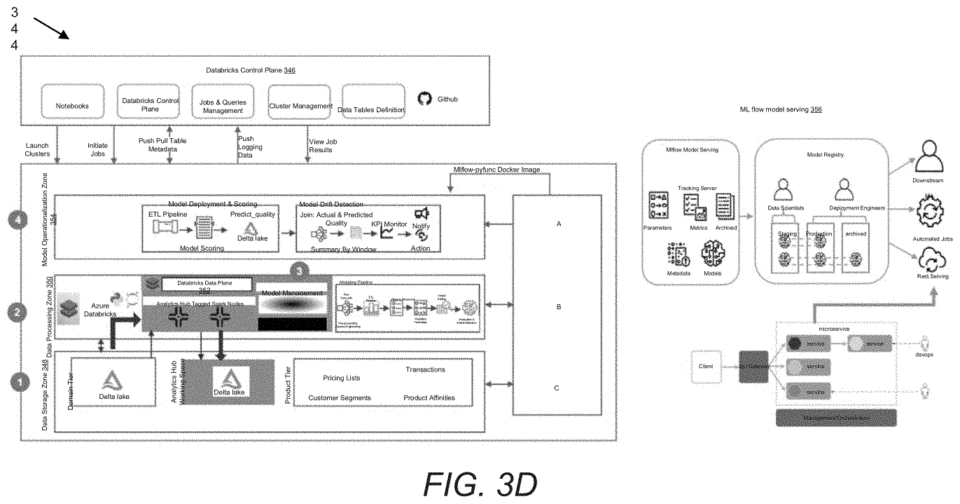

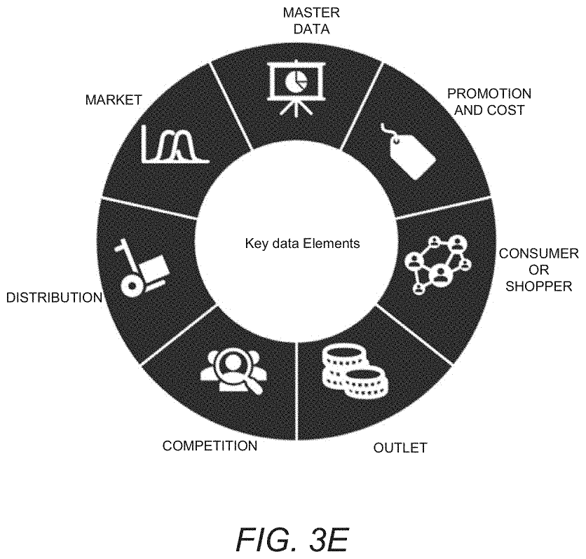

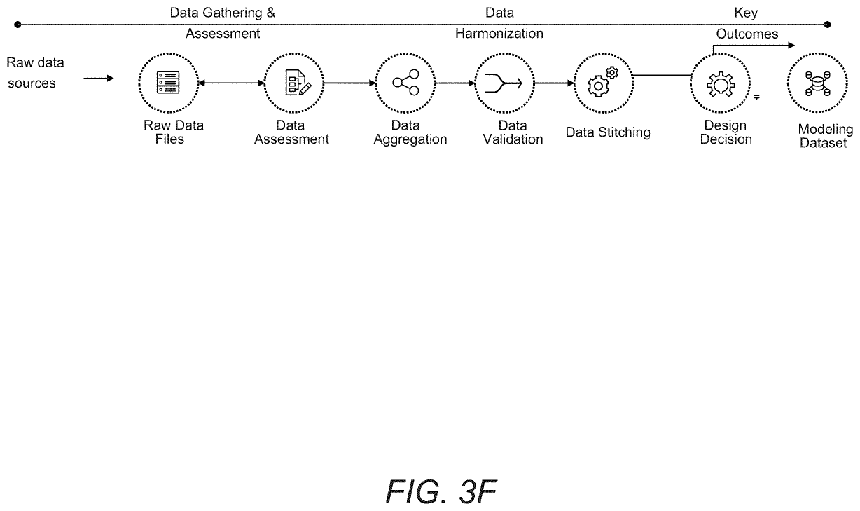

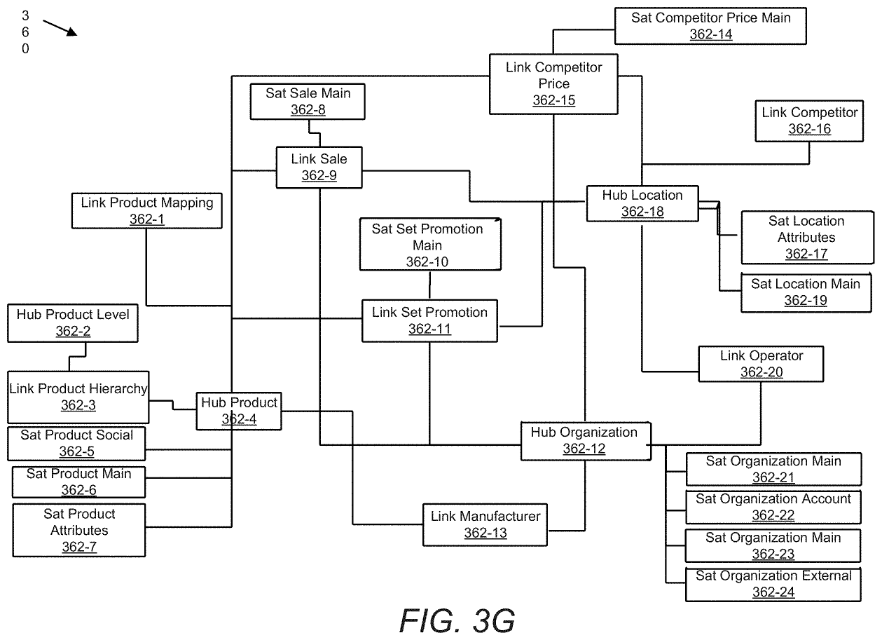

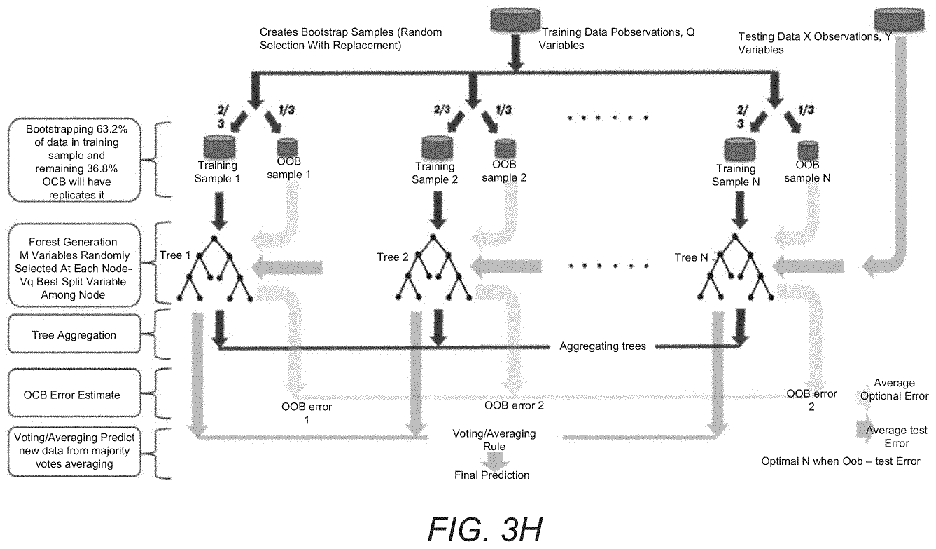

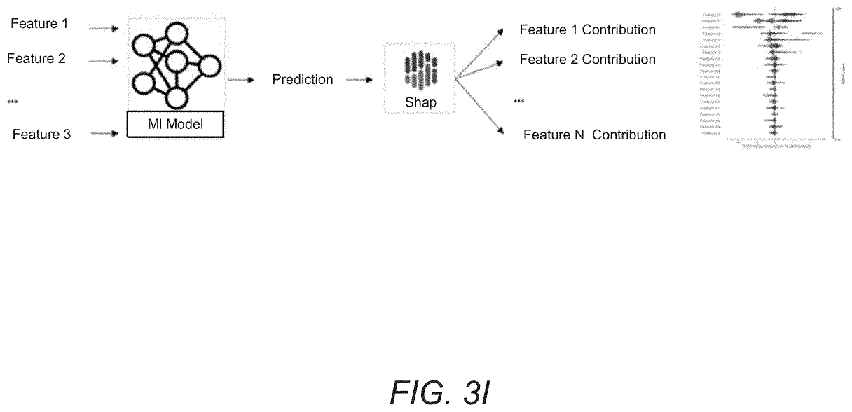

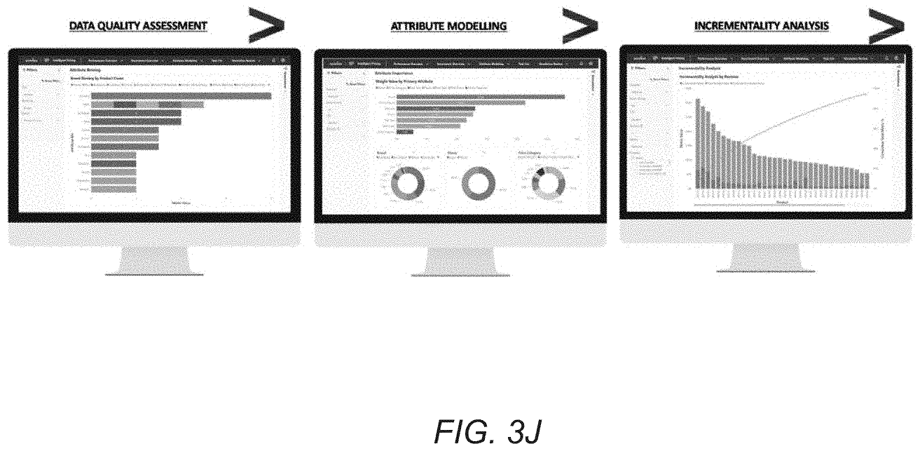

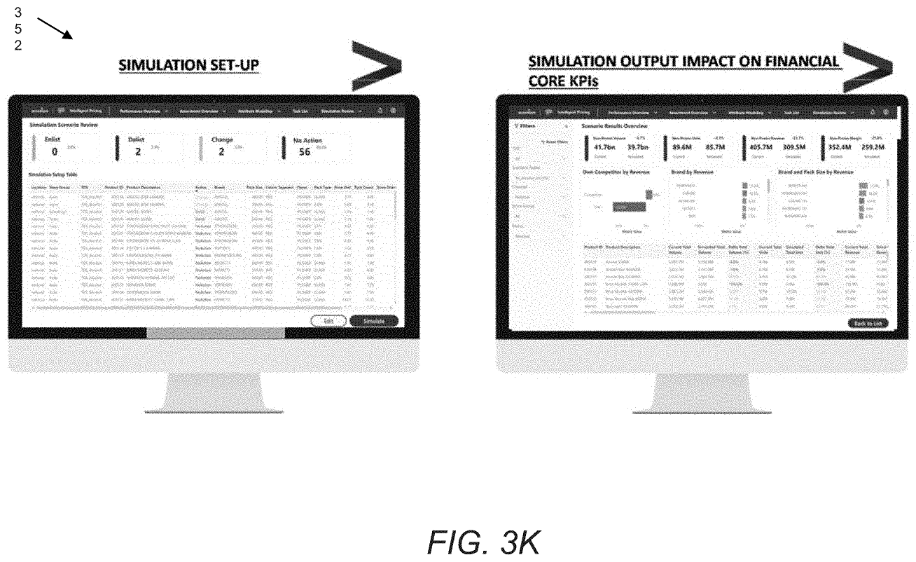

FIG. 3A illustrates an exemplary diagram depicting an outcome of the system 200, according to an example embodiment of the present disclosure. The input to the attribute-based sales decomposition system 202 may include industrialized data foundation powered by Artificial Intelligence (AI) and the output may be sent to value realization and adoption of the data in action. The attribute-based sales decomposition system 202 may have key outcome which may be performed by a pre-configured azure tech stack 302, a ML algorithm 304 (random forest), a business enablers and functional expertise 306, a unified data model using data vault 308, a game theory framework (SHAP) 310, and an insight to action value realization support 312 which include client, retailers and shoppers. The business enablers may calculate the demand transferability 238. The algorithms in the attribute-based sales decomposition system 202 may quantify the importance and significance of each of the product attribute, which may be split or estimate the contribution of each product attributes to the total sale. This can be scaled across thousands of products to estimate the demand transferability 238.

The building blocks such as the pre-configured azure tech stack 302, the ML algorithm 304 (random forest), the business enablers and functional expertise 306, the unified data model using data vault 308, and the game theory framework (SHAP) 310 may perform data driven decisions in Price Pack Architecture (PPA) and product assortment mixture using the attribute-based sales decomposition system 202. The pre-configured azure tech stack 302 may include native azure components which may be used for infinite scale on plurality of product and attribute combinations across different markets. Further, the unified data model using data vault 308 may include data agnostic and flexible data modeling using data vault methodology to accommodate multiple variations of external and internal data for consumer goods and retail industries. The ML algorithm 304 (random forest) may include applied intelligence such as modeling algorithm, which uses non-parametric ML models to unravel the relationship of product attributes on product non promotional sales. The game theory framework (SHAP) 310 may be an interpretable AI such as a game theory which includes a game theoretic framework (SHAP) 310 to quantify the contribution of each product attribute to the prediction made by the ML model/ML algorithm 304 for each product individually. Further, the business enablers and functional expertise 306 may provide key outcome such as demand transferability which utilizes product attribute importance to estimate the transferable demand for each product in hypothetical scenarios of portfolio reduction/change/increase.

Logical components of the pre-configured azure tech stack 302 may be shown in FIG. 3B. The pre-configured azure tech stack 302 may perform design and act logic 312 based on decisioning capabilities to enable front end to capture user input, apply business rules and trigger ML models. The design and act logic 312 may include real-time decisioning and low code applications. A pragmatic workflow in the design and act logic 312 may create and compare scenarios vs. base plan, provide recommended changes to key account manager and so on. The pragmatic workflow may be convenient for the business users to plan/review and execute. The design and act logic 312 may provide advanced predictive analytics which includes predictive insights to notify the user of the risks and opportunities, prompting the user to adjust plans and trigger corrective actions, basis the advanced analytical engine at the back-end. Furthermore, the design and act logic 312 may perform what-ifs and scenario comparison. The what-ifs and scenario comparison may provide flexibility to create what-if scenarios and select multiple scenarios for comparison, review, and seek/provide approval. Helps the user identify executional challenges if there are any flexible lever selection. Further, the design and act logic 312 may provide strategy setting and guardrails in which the user can define the strategy, scope; business guardrails (product, attributes) in the ‘what if’ simulation problem structure. Furthermore, the design and act logic 312 may provide optimal revenue growth plan and generate optimal plan based on strategy created and view business KPIs (i.e., planned vs. optimized). The design and act logic 312 may provide details of changes to assortment, portfolio mix, regular pricing.

Further, the pre-configured azure tech stack 302 may perform a monitor and operate logic 314 based on monitoring brand performance (descriptive dashboards) and test complex scenarios through triggering advanced analytics simulation. The monitor and operate logic 314 may provide visualization of the data and in some instance low code applications. The monitor and operate logic 314 may include business overview and diagnostics which includes overview of performance and Key Performance Indicators (KPIs) by channel, brand, Stock Keeping Unit (SKU). Further, the monitor and operate logic 314 may identify areas which need intervention based on latest data and tailor alerts/notifications for key users, and guide diagnostics through user prompts.

Furthermore, the pre-configured Azure tech stack 302 may include application engine 316 which may include microservices that interact between, front-end, back-end and core components. The application engine 316 may include containers and API layer. Thereafter, the pre-configured azure tech stack 302 may include a transaction core 318 which may include common data model that may capture multiple user actions and simulation scenarios. The transaction core 318 may include data vault. Further, the pre-configured azure tech stack 302 may include a collect and process logic 320 which may collect and process data through data Extract, Transform and Load (ETL) flows, consolidated in the landing zone and create a processed data store. The collect and process logic 320 may include data supply chain. Furthermore, the pre-configured azure tech stack 302 may include an infer and reason logic 322 for performing attribute base models (through random forest and using SHapley Additive exPlanations (SHAP) values algorithms) to understand promotional performance and assess the attribute importance and the demand transferability. Thereafter, the infer and reason logic 322 may provide embedded advanced analytical/ML/AI, which may include advanced analytical, attribute base machine learning approaches embedded at different stages throughout the tool and processes.

Further, the pre-configured azure tech stack 302 may include automate and orchestrate logic 324 for performing orchestration and administration of the pre-configured azure tech stack 302. The automate and orchestrate logic 324 may include platform services, security and governance, and process automation data.

FIG. 3C illustrates an exemplary block diagram representation of Azure® architecture 330, according to an example embodiment of the present disclosure. The azure architecture 330 may include main components such as an azure data lake storage 332, an azure data bricks and operational database 334, a model development and testing 336, a power Business Intelligence (BI) reports 338, an API management 340, and a model service and micro service 342. The azure data lake storage 332 may collect and process in which raw data may be ingested into the azure data lake storage 332. The data may be cleaned, transformed and organized into different zones for consumption. Azure data factory (pipelines), Azure data lake (storage) and azure data bricks (analytics) may be the backbones for building a unified cloud scale data platform. The operational database may be replaced with the earlier choice of cosmos database with azure SQL as power BI may not have direct query support to cosmos db.

Further, the azure data bricks and operational database 334 may be a transactional core which includes design and build metadata for model versioning, model performance, model output, action recommendation/simulation. Furthermore, the model development and testing 336 may be the infer and reason logic which may train and build the ML models using Python®, R®. The users may have advantage of the inbuilt capabilities of azure data bricks to perform root cause determination and raw data analysis. Thereafter, the power BI reports 338 may be the monitor and operate logic which may provide analytics platform to serve business intelligence reports via power BI. The API management 340 may be the decide and act logic which includes, power apps, business rules to be triggered on scored results/recommendations (what-if simulation in power BI, model simulation tabs in power BI/power apps). Further, the model service and micro service 342 may be the application engine in which insights from models may be stored in azure SQL to make the insights accessible through web. The azure architecture 330 may leverage a microservices design deployed on azure functions. The model serving may be the data bricks which provides model serving capabilities which may be in preview mode. For high volume, Kubernetes® can be considered for hosting the model.

FIG. 3D illustrates an exemplary block diagram representation of an azure analytical model 344, according to an example embodiment of the present disclosure. The azure data lake storage 332 may include a data storage zone 348. The data storage zone 348 may include transactions, scalable metadata handling, and unifies streaming and batch data processing. The azure data bricks and operational database 334 may include a data processing zone 350 which includes the model development and testing 336 for the data bricks, a data bricks data pane 352 and model management, modelling pipeline. The power BI reports 338 may include a model operationalization zone 354 which includes model deployment and scoring, model drift detection. The model service and micro service 342 may include ML flow model serving 356 which includes tracking server and model registry. The data bricks may provide ML flow model serving 356, which helps hosting machine learning models from the model registry as REST endpoints that may be updated automatically based on the availability of model versions and their stages. The ML flow model serving 356 may be available for Python® ML flow models.

FIG. 3E illustrates an example schematic diagram representation of data elements including external and internal sources, according to an example embodiment of the present disclosure. The external and internal sources may include market data, master data, promotion data, cost data, consumer data and shopper data, outlet data, competition data, and distribution data. The market data may include but not limited to, product sales at region, channel, or retailer level, product preference surveys, and the like. In an example embodiment, the market attribute may pertain to increase/decrease in product vending as evaluated based on market survey/research such as, for example, trend, seasonality, special events, public holidays, product preference surveys and other such aspects. The master data may include, but not limited to, price, product hierarchy, attributes, and the like. The promotion and cost data may include, but not limited to, promotion calendar, mechanic, support (display, feature etc.), trade spend, promotion investment, inventory cost, cost of goods sold (COGS), LOGS, and the like. The term “promotional mechanics” may pertain to a strategy of engaging consumers in a product campaign/interactive event by ensuring guaranteed rewards. In an example embodiment, pricing attribute may pertain to aspects that influence product price such as trade spend, promotion investment, inventory cost, cost of goods sold (COGS) and other aspects. The term “trade spend” may pertain to amount of money that a manufacturer provides to a product vendor (product vending entity) for the purposes of vending the product to consumers. The COGS may pertain to direct costs of manufacturing the product, which includes the cost of the materials and labor directly used to manufacture the product. The consumer data or shopper data may include, but not limited to, purchase frequency, share of wallet, socio-demographic data, demographics, lifestyle, macro-economic factors, and the like. In an example embodiment, the consumer data may pertain to at least one of purchase frequency, Share of Wallet (SOW), socio-demographic data or demographics, lifestyle of consumer, macro-economic factors and other such information associated with a consumer of the product. The SOW may provide information pertaining to an amount that an existing consumer may spend regularly on a product from a particular entity/brand instead of choosing the products from competing brands/entities. The socio-demographic data may indicate characteristics of a consumer with respect to at least one of age, gender, ethnicity, education level, income, type of consumer, nature of profession, location of the consumer, marital status, family attributes, nationality, other information related to the consumer, and the like. The lifestyle of the consumer may indicate the purchase routines/preferences of the consumer based on their affordability. The product vending or demand of a product may also be influenced as per the macro-economic factors. For example, aspects such as fiscal parameters, natural parameters, or geopolitical event can largely affect a regional or national economy, which in turn may also affect product demand. The macro-economic factors may include parameters such as, for example, gross domestic product (GDP), employment rate, inflation rate, government debt and other such aspects. The collection of data pertaining to consumer data may thus enable to evaluate general/specific affordability of a population and/or demand of the product based on different types of consumers.

The outlet data may include, but not limited to, store location, outlet proximity, location attributes, and the like. In an example embodiment, the outlet data may pertain to storage/vending site of the product such as, for example, location/store at which product may be available for vending, proximity of the store to a location with high traffic and other location-based characteristics. The competition data may include, but not limited to, competitor price, promotion, product attributes, market share, and the like. The competition data may include attributes of a competitor product of similar category/type manufactured by a competitor entity/brand. Further, the distribution data may include, but not limited to, inventory/stock-out, in-store availability, and the like. The term “stock-out” may pertain to an order by a consumer that may exceed the stock of the inventory, which also indicates increase in demand of the product. In an example embodiment, the data pre-processor 110 may pre-process the raw dataset collected from a raw data source to generate the input dataset. The raw data source includes at least one of, the internal source and the external source storing raw data pertaining to the one or more data elements.

FIG. 3F illustrates an example flow diagram representation depicting a pre-processing and harmonization of raw data, according to an example embodiment of the present disclosure. As illustrated in 3F, the raw dataset (or raw data files) from raw data sources may be collected by the data pre-processor 110 (of FIG. 1). In an example embodiment, the raw dataset may be collected and assessed followed by data harmonization. This may include assessing and analyzing large amount of diverse data using advanced analytics, open-source technologies, best practices to unlock the potential of data. The data gathering and assessment may include raw data files and assessment. The data may be gathered from client, third party such as Nielsen/Information Resources, Inc (IRI) and so on, and stage it for further data processing. The data quality assessment may be to check and identify the missing information and ensure that all the data may be ready for processing, incorporate feedback from the business in case of any data gaps, and transform any unstructured data into easily ingestible templates for the ease of data processing. In an example embodiment, the assessment of the raw dataset may be performed to identify presence of missing information such that the assessed dataset may be processed for data structuring for transformation into a structured dataset. The data harmonization may include data aggregation, data validation, and data stitching. In an example embodiment, the missing information may be replaced with a feedback-based data to obtain an assessed dataset. The assessed dataset may be transformed to convert an unstructured data into easily ingestible templates for the ease of data processing. The data aggregation may include aggregating data at the planning level for analysis. The data aggregation may combine one or more digital documents in the structured dataset into an aggregated dataset. The data validation may be sales matching for matching primary sales from database with Nielsen/IRI data, promotion merging for validating promotion calendar against the epos/syndicated sales data, data quality for treating data for missing values, outlier treatment and business inconsistencies. The data validation may also include assessment of data quality by performing at least one of treatment of data for missing values, treating for identification/removal of outlier values and correction of occupational inconsistencies. The data stitching may be a feature engineering for stitching the validated data, creating variables and applying transformations for statistical modeling purpose. The key outcomes may include design decision and modelling dataset. This includes basis of the data exploration and validation to arrive at the design decision for analytical process, scope of analysis may be finalized along with the possible range of insights, modeling dataset from the previous step goes as an input for all the modeling and analysis purpose. In an example embodiment, the system 100 may also include the data vault generator 108 to generate the data vault representation. The data vault representation may include relevant information pertaining to the product attributes. Each data point may store information corresponding to the one or more data elements associated with the product attributes. In an example embodiment, the data vault representation may be generated using at least one of the raw datasets and the input dataset.

FIG. 3G illustrates example flow diagram depicting an atomic data model in a data vault schema, according to an example embodiment of the present disclosure. As illustrated in FIG. 3G, a data vault representation 360 illustrates various data elements that are interlinked to depict an association between the data elements that are interlinked. In an example embodiment, the data vault representation may be in the form of an atomic data model, as illustrated in FIG. 3G. The atomic data model in the data vault schema in the data vault representation 360, may facilitate to decouple raw data from a platform. In the instant embodiment, the platform may remain decoupled from data foundation by adopting a layered data modelling approach. In this approach, instead of transforming the raw data directly to an analytical data model, the raw data may be first mapped to the atomic data model. The atomic data model may be then transformed to the analytical data model. The solution/system may be designed for scaling taking into consideration the differences that might occur based on change in location or country. For example, in case of a global roll out, variation in data granularity may be observed. The data vault representation or atomic model may be a simplified form of data model as it allows only specific types of relationships between three basic entities. For example, the three basic entities may be product, organization and location. This approach may prevent ambiguity due to limited features/factors being considered. This may also lead to a consistent outcome even when the approach is implemented by different people and/or different teams involved in data modelling at different points in time. In an example embodiment, the entity details may be attached as separate data tables to a master data entity. This may allow the future customization for different markets by changing the entity details but not changing the master data entities. For example, the entity details related to entity (product) may include, for example, product attributes and/or product hierarchy, which may be attached to a product master data entity. In an alternate example embodiment, data entities may be needed to model relationships between master data entities. For example, a sale transaction may be a relationship between a product, a customer, a sale location and other such factors. Further, the atomic data model may include relationship links that may be unique identifiers within master data entities. However, the relationship links may not be created between entity details or between other relationships. In an example embodiment, the atomic data model may also include reference data entities such as, for example, calendar, currencies and other such entities, which may be captured using Data Vault terminology. Typical atomic data model may include terms/representation in a standard format, such as, for example, master data entities represented as HUBS (_HUB). For example, as illustrated in FIG. 3G, the master data entity (HUBS) may pertain to entities as product (HUB product level 362-2, HUB product 362-4), organization (HUB organization 362-12) and location (HUB location 362-18). The entity details may be represented as SATELLITES (_SAT). For example, as illustrated in FIG. 3G, the entity details (SATELLITES) may include details about the master entity such as, for example, SAT product social 362-5, SAT product main 362-6 and SAT product attributes 362-7 may relate to details pertaining to product as the entity (HUB product 362-4). In another example, the master entity location (HUB location 362-18) may include entity details such as, for example, SAT location attributes 362-17, SAT location main 362-19. In yet another example, the master entity such as organization (HUB organization 362-12) may include entity details such as, for example. SAT organization main (362-21), SAT organization external 362-24 and SAT organization account 362-22. Further, the relationship links may be represented as LINKS (_LINK). For example, the HUB product 362-4 and the HUB product level 362-2 may be linked by a relationship i.e., LINK product hierarchy 362-3. In another example, the HUB product 362-4 and the HUB organization 362-12 may be linked by a relationship i.e., LINK manufacturer 362-13. In yet another example, the HUB organization 362-12 and the HUB location 362-18 may be linked by a relationship i.e., LINK operator 362-20 and LINK sale 362-9. In yet another example, the HUB location 362-18 and the HUB product 362-4 may be linked by a relationship i.e., LINK product mapping 362-1, LINK competitor price 362-15 and LINK competitor 362-16. In yet another example, the HUB product 362-4, the HUB organization 362-12 and the HUB location 362-18 may be linked by a relationship i.e., LINK set promotion 362-11. Further, each link may be associated with link details (SAT). For example, the link details related to LINK sale 362-9 may be SAT sale main 362-8. The link details related to LINK competitor price 362-15 may be SAT competitor price main 362-14. The link details related to LINK set promotion 362-11 may be SAT set promotion 362-10. Furthermore, the reference data may be represented as REFERENCE (_REF). It may be appreciated that the atomic data model provided in FIG. 3g may be exemplary and hence may not be limited by the mentioned entities and/or relationships, which may vary with variation in other factors.

FIG. 3H illustrates an exemplary flow diagram depicting working of decision trees, according to an example embodiment of the present disclosure. In an instance, random forests may be an ensemble ML method for classification, regression that constructs a multitude of decision trees predicting the mode of the classes (classification) or mean prediction (regression) of the individual trees. The random forest may build multiple decision trees (for either classification and regression use cases) and merges them together to get a more accurate and stable prediction. The random forest may be an ensemble classifier using many decision tree models based on bootstrapped sample of data and random selection of variables. The random forest may provide the class of dependent variable based on many trees. The method combines Breiman's “bagging” idea and random selection of features. The bootstrapping is executed on the training data (63% of total). Each tree may be grown on training data and remaining 37% of the data may be used for Out of Bag (OOB) validation. At each node ‘R’ number of variables may be randomly selected to create the tree. (R may be recommended to be square root of total number of predictors). A large number of trees may be developed using bootstrapping and sampling. The trees may then be combined via voting/averaging for prediction.

FIG. 3I illustrates exemplary flow diagram depicting working of a ShaPley Additive exPlanations (SHAP), according to an example embodiment of the present disclosure. The SHAP may quantify model subcomponents of model output by leveraging the principles of cooperative game theory. The SHAP may utilize cooperative game theory to quantify the contribution of individual features corresponding to the product attributes and attribute values. The SHAP can be applied to wide range of algorithms that the users can select from, to suit the ML approach based on the required predictions that need to be explained. A model specific approaches may include linear SHAP, deep SHAP, and tree SHAP. The linear SHAP may include approximating SHAP values through weights assuming feature independence. The deep SHAP may leverage a combination of Deep Lift method and SHapley values deep Lift using “summation to delta” property to map differences (from base to specific input) in input to the specific model output values. Differences in output (from base to specific output). For linear regression, it simplifies to linear approximation for deep learning-based models. The tree SHAP may average differences in predictions over all possible orderings of the features. Further, a model agnostic may include a kernel SHAP (linear LIME+SHAPley) which leverages a combination of local linear approximations and weighting kernel using a heuristically selected loss function.

The Linear SHAP may be as shown in equation 1 below:

Given a linear model f(x)=Σⱼ₌₁^{M}wⱼxⱼ+b:φ₀(f,x)=b and

φᵢ(f,x)=wⱼ(xⱼ−E[xⱼ])

In the above equation 1, the SHAP values ‘φi’ may be approximated directly from the model's weight coefficients. Further, the Deep LIFT SHAP may be as shown in equation 2 below:

$${\sum }_{i = 1}^{n} {c}_{{Δ}_{{x}_{i}} {Δ}_{o}} = {Δ}_{o} \qquad Equation 2$$

In the above equation 2, the Deep LIFT attributes to each input ‘xi’, a value CΔxiΔy that represents the effect of that input may be set to a reference value as opposed to its original value. This means that for Deep LIFT, the mapping x=hx(x′) converts binary values into the original inputs, where ‘1’ indicates that an input takes its original value, and ‘0’ indicates that it takes the reference value. The Deep LIFT uses a “summation-to-delta” property as stated in the above equation 2,
In the above equation 2, the term o=f(x) may refer to the model output, Δo=f(x)−f(r), Δxi=xi−ri and r is the reference input (value 0).
Furthermore, the Tree SHAP averages differences in predictions over all possible orderings of the features.

$${φ}_{i} ( N , v ) = {E}_{σ} [ {m}_{i} ( σ ) ] = \frac{1}{n !} {\sum }_{σ ∈ \prod N} {m}_{i} ( σ ) \qquad Equation 3$$

In the above equation 3, the term φᵢ(N, v) may refer to the attributed SHAP value for feature I, the term ‘n’ may refer to the number of features of the input, the term ‘r’ may refer to all the possible orderings of the input feature set N, the term ‘mᵢ(σ)’ may refer to the difference in prediction when ordering i is included/excluded. Furthermore, the kernel SHAP may be as shown in equation 4 below:

$$L ( f , g , {π}_{{x}^{′}} ) = {\sum }_{{z}^{′} ∈ Z} {[ f ( {h}_{x}^{- 1} ( {z}^{′} ) ) - g ( {z}^{′} ) ]}^{2} {π}_{{x}^{′}} ( {z}^{′} ) \qquad Equation 4$$

In the above equation 4, the term |z′| may refer to the number of non-zero elements in z′, the term ‘g(z′)’ may be assumed to follow a linear form g(z′)=φ₀+Σᵢ₌₁^{M}φᵢz′ᵢ, where the term z′∈{0,1}^{M}, M may refer to the number of simplifies input features, and p E R. and L may refer to a squared loss, the term f may refer to the original prediction model to be explained and g the explanation model. Methods with explanation models matching Definition 1 attribute an effect φi to each feature, and summing the effects of all feature attributions approximates the output f(x) of the original model. Faithfulness of the explanation model g(z′) to the original model f(hx(z′)) is enforced through the loss L over a set of samples in the simplified input space weighted by the local kernel πx′ as shown in equation 5 below:

$$weighting kernel {π}_{{x}^{′}} = \frac{( M - 1 )}{( M choose \vert {z}^{′} \vert ) \vert {z}^{′} \vert ( M - \vert {z}^{′} \vert )} \qquad Equation 5$$

The ML approach based on the required predictions that need to be explained may include a model explain-ability approach. The model explain-ability approach may be evaluated on suitability for the model and requirement for explain-ability based on relative feature importance and feature contribution. The ML model explain-ability approach may include a Wald-Chi Square and T-Value which leverages either the Wald-Chi Sq or absolute t-statistic. A weighted average of the respective statistic may be taken which provides a rough but practical importance of each feature. The ML model explain-ability approach may not be suitable for ML model, and may not work directly for ML based approaches and requires approximate regressions, which may require incorporating interaction-based terms. Further, the ML model explain-ability approach may include reduction in errors which includes reduction in the model error across decision nodes may be used as a measure to quantify the impact of feature in the overall model. The ML model explain-ability approach may be suitable for ML model which may be primarily leveraged for boosting based approaches, e.g., gradient boosting trees, extra trees & cat boost. Further, the ML model explain-ability approach may include SHAP which may leverage cooperative game theory to quantify the contribution of individual features and provides a wide range of algorithms. SHAP leverages perturbed samples to quantify the contribution of a given prediction. Hence, this may be suitable for interpreting black box machine learning models. The ML model explain-ability approach may be suitable for ML model which may offer a wide range of algorithms for different ML approaches as well as a model agnostic approach. Hence, the ML model explain-ability approach may enable model explain-ability irrespective to the ML algorithm that may be used. Furthermore, the ML model explain-ability approach may include mutual information-based scorecard which may identify the relative weight of individual variables based on the information value of individual variables. The ML model explain-ability approach may not be suitable for ML model, since it may be extremely complex to use and understand and requires significant calculations. Hence ML model explain-ability approach may not be suitable for ML model.

FIG. 3J illustrates a graph diagram of attribute-based modelling outputs, according to an example embodiment of the present disclosure. In the data quality assessment, questions the view answers may include: which may be the available product attributes, which SKUs qualify for the ABM analysis, is there any missing values and which may be the remedy actions, which product attributes will be included in the ABM and on which we can simulate scenarios. Further, the attribute modelling, questions the view answers may include: what attributes to consumers really care about, what is the relative importance of attributes, are there “redundant” attributes that allow us to simplify without loss of volume, what are the differences in relative importance of pack prices and attributes by channel. Further, an incrementality analysis, questions the view answers may include: what will happen if a SKU is deleted, which portion of a SKU sales will be transferred to the rest of the products (base sales) and which will be lost (incrementality) when an SKU is delisted. FIG. 3K illustrates a schematic diagram of testing and validation of attribute-based modelling, according to an example embodiment of the present disclosure. The simulation set up, questions the view answers may include: what are all the changes that need to simulate, select and change a given set of product attributes in order to simulate the effects (volume and profit and loss financial impacts) of a different pack price SKU mix for the selected retailer, de-select a subset of already existing SKUs part of the current portfolio and simulate volume and profit and loss financial impact at category, brand and retailer level. Further, the simulation set up may include simulate new product launches volume and profit and loss financial impacts select a given set of product attributes identifying a new product (different pack price SKU mix) not currently existing within the portfolio (existing in another retailer though). Further, a simulation output impact on financial and core KPIs, questions the view answers may include: what if a SKU is delisted or enlist a new SKU or change the attributes of an existing SKU? What is the impact on units' sales, revenue and profit from scenario planning? How is this compared to the current state and other scenarios?

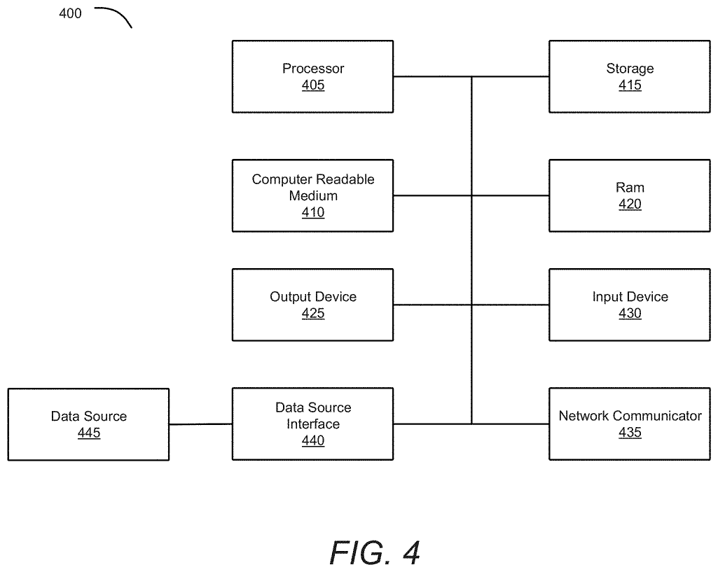

FIG. 4 illustrates a hardware platform 400 for implementation of the disclosed system, according to an example embodiment of the present disclosure. For the sake of brevity, construction and operational features of the system 100 which are explained in detail above are not explained in detail herein. Particularly, computing machines such as but not limited to internal/external server clusters, quantum computers, desktops, laptops, which may be used to execute the system 100 or may include the structure of the hardware platform 400. As illustrated, the hardware platform 400 may include additional components not shown, and that some of the components described may be removed and/or modified. For example, a computer system with multiple GPUs may be located on external-cloud platforms including Amazon Web Services, or internal corporate cloud computing clusters, or organizational computing resources, etc.

The hardware platform 400 may be a computer system such as the system 100 that may be used with the embodiments described herein. The computer system may represent a computational platform that includes components that may be in a server or another computer system. The computer system may execute, by the processor 405 (e.g., a single or multiple processors) or other hardware processing circuit, the methods, functions, and other processes described herein. These methods, functions, and other processes may be embodied as machine-readable instructions stored on a computer-readable medium, which may be non-transitory, such as hardware storage devices (e.g., RAM (random access memory), ROM (read-only memory), EPROM (erasable, programmable ROM), EEPROM (electrically erasable, programmable ROM), hard drives, and flash memory). The computer system may include the processor 405 that executes software instructions or code stored on a non-transitory computer-readable storage medium 410 to perform methods of the present disclosure. The software code includes, for example, instructions to gather data and documents and analyze documents. In an example, the attribute-based decomposition engine 102, may be software codes or components performing these steps.

The instructions on the computer-readable storage medium 410 are read and stored the instructions in storage 415 or in random access memory (RAM). The storage 415 may provide a space for keeping static data where at least some instructions could be stored for later execution. The stored instructions may be further compiled to generate other representations of the instructions and dynamically stored in the RAM such as RAM 420. The processor 405 may read instructions from the RAM 420 and perform actions as instructed.

The computer system may further include the output device 425 to provide at least some of the results of the execution as output including, but not limited to, visual information to users, such as external agents. The output device 425 may include a display on computing devices and virtual reality glasses. For example, the display may be a laptop screen. GUIs and/or text may be presented as an output on the display screen. The computer system may further include an input device 430 to provide a user or another device with mechanisms for entering data and/or otherwise interact with the computer system. The input device 430 may include, for example, a keyboard, a keypad, a mouse, or a touchscreen. Each of these output devices 425 and input device 430 may be joined by one or more additional peripherals. For example, the output device 425 may be used to display the results such as product attributes importance.

A network communicator 435 may be provided to connect the computer system to a network and in turn to other devices connected to the network including other clients, servers, data stores, and interfaces, for instance. A network communicator 435 may include, for example, a network adapter such as a LAN adapter or a wireless adapter. The computer system may include a data sources interface 440 to access the data source 445. The data source 445 may be an information resource. As an example, a database of exceptions and rules may be provided as the data source 445. Moreover, knowledge repositories and curated data may be other examples of the data source 445.

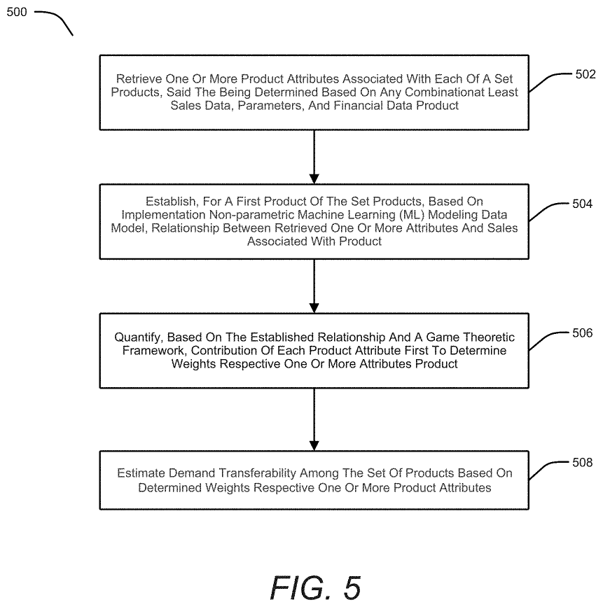

FIG. 5 illustrates a flow diagram depicting method 500 of attribute-based modelling, according to an example embodiment of the present disclosure.

At block 502, the method 500 may include retrieving, by the processor 104, one or more product attributes associated with each of a set of products, an importance of the one or more product attributes being determined based on the product sales data, product data, product parameters, and financial data associated with the product

At block 504, the method 500 may include establishing, by the processor 104, for the set of products a relationship between the retrieved one or more product attributes and product sales associated with the product, based on the implementation of non-parametric machine learning (ML) modeling on a data model.

At block 506, the method 500 may include quantifying, by the processor 104, a contribution of each product attribute on the product sales, based on the established relationship and a game theoretic framework. The contribution of each product attribute on the product sales is quantified to determine weights of the respective product attributes.

At block 508, the method 500 may include estimating, by the processor 104, demand transferability among the set of products based on the determined weights of the respective product attributes.

The order in which the method 500 are described is not intended to be construed as a limitation, and any number of the described method blocks may be combined or otherwise performed in any order to implement the method 500 or an alternate method. Additionally, individual blocks may be deleted from the method 500 without departing from the spirit and scope of the present disclosure described herein. Furthermore, the method 500 may be implemented in any suitable hardware, software, firmware, or a combination thereof, that exists in the related art or that is later developed. The method 500 describe, without limitation, the implementation of the system 100. A person of skill in the art will understand that method 500 may be modified appropriately for implementation in various manners without departing from the scope and spirit of the disclosure.

One of ordinary skill in the art will appreciate that techniques consistent with the present disclosure are applicable in other contexts as well without departing from the scope of the disclosure.

What has been described and illustrated herein are examples of the present disclosure. The terms, descriptions, and figures used herein are set forth by way of illustration only and are not meant as limitations. Many variations are possible within the spirit and scope of the subject matter, which is intended to be defined by the following claims and their equivalents in which all terms are meant in their broadest reasonable sense unless otherwise indicated.

We claim:

1. A system comprising:
an attribute-based decomposition engine, which when executed using a processor, causes the engine to:
retrieve one or more product attributes associated with each of a set of products, an importance of the one or more product attributes being determined based on product sales data, product data, product parameters, and financial data associated with the product;
establish, for the set of products, a relationship between the retrieved one or more product attributes and product sales associated with the product, based on the implementation of non-parametric machine learning (ML) modeling on a data model;
quantify a contribution of each product attribute on the product sales, based on the established relationship and a game theoretic framework, wherein the contribution of each product attribute on the product sales is quantified to determine weights of the respective product attributes; and
estimate demand transferability among the set of products based on the determined weights of the respective product attributes.

2. The system as claimed in claim 1, wherein the demand transferability is indicative of a uniqueness of each product of the set of products.

3. The system as claimed in claim 1, wherein the processor is further configured to transfer a quantification of potential volume to other products or potentially lost from a given product category in instances of reduction, change, or increase in product portfolio.

4. The system as claimed in claim 1, wherein the non-parametric machine learning (ML) modeling is based on Random Forest Algorithm.

5. The system as claimed in claim 1, wherein metadata associated with the non-parametric machine learning (ML) modeling is selected from at least one of automated model hyper parameter tuning, a log of automated experiment iterations, ML model parameters, and valuation and performance metrics.

6. The system as claimed in claim 1, wherein the game theoretic framework is based on SHapley Additive exPlanations (SHAP) approach that processes the relationship established by the machine learning (ML) modeling to enable the quantification of the contribution of each product attribute on the product sales, based on the established relationship and the game theoretic framework.

7. The system as claimed in claim 1, wherein the data model is implemented based on a data agnostic and flexible data modeling technique to accommodate variation of external and internal data associated with the set of products.

8. The system as claimed in claim 1, wherein the data model is generated based on:
ingestion and storage of raw data associated with the set of products from a plurality of sources;
design and development of metadata for at least one of model versioning, model performance, model output, and action recommendation/simulation; and
building of the data model based on training using the ingested data and the developed metadata.

9. The system as claimed in claim 1, wherein the one or more product attributes are based on at least one of product sale/price data, product hierarchy, promotion and cost, target consumer, outlet location, product availability, outlet location attributes, competition, product distribution, target audience/market, and product parameters.

10. A method for attribute-based modelling comprising:
retrieving, by a processor, one or more product attributes associated with each of a set of products, an importance of the one or more product attributes being determined based on product sales data, product data, product parameters, and financial data associated with the product;
establishing, by the processor, for the set of products, a relationship between the retrieved one or more product attributes and the product sales associated with the product, based on the implementation of non-parametric machine learning (ML) modeling on a data model;
quantifying, by the processor, a contribution of each product attribute on the product sales, based on the established relationship and a game theoretic framework, wherein the contribution of each product attribute on the product sales is quantified to determine weights of the respective product attributes; and
estimating, by the processor, demand transferability among the set of products based on the determined weights of the respective product attributes.

11. The method as claimed in claim 10, wherein the demand transferability is indicative of a uniqueness of each product of the set of products,

12. The method as claimed in claim 10 further comprising transferring, by the processor, quantification of potential volume to other products or potentially lost from a given product category in instances of reduction, change, or increase in product portfolio.

13. The method as claimed in claim 10, wherein the non-parametric machine learning (ML) modeling is based on Random Forest Algorithm.

14. The method as claimed in claim 10, wherein metadata associated with the non-parametric machine learning (ML) modeling is selected from at least one of automated model hyper parameter tuning, a log of automated experiment iterations, ML model parameters, and valuation and performance metrics.

15. The method as claimed in claim 10, wherein the game theoretic framework is based on SHapley Additive exPlanations (SHAP) approach that processes the relationship established by the machine learning (ML) modeling to enable the contribution of each product attribute on the product sales, based on the established relationship and the game theoretic framework.

16. The method as claimed in claim 10, wherein the data model is implemented based on a data agnostic and flexible data modeling technique to accommodate variation of external and internal data associated with the set of products.

17. The method as claimed in claim 10, wherein the data model is generated based on:
ingesting, by the processor, and storage of raw data associated with the set of products from a plurality of sources;
designing, by the processor, and development of metadata for at least one of model versioning, model performance, model output, and action recommendation/simulation; and
building, by the processor, of the data model based on training using the ingested data and the developed metadata.

18. The method as claimed in claim 10, wherein the one or more product attributes are based on at least one of product sale/price data, product hierarchy, promotion and cost, target consumer, outlet location, product availability, outlet location attributes, competition, product distribution, target audience/market, and product parameters.

19. A non-transitory computer readable medium, wherein the readable medium comprises machine executable instructions that are executable by a processor to:
retrieve one or more product attributes associated with each of a set of products, an importance of the one or more product attributes being determined based on product sales data, product data, product parameters, and financial data associated with the product;
establish, for the set of products, a relationship between the retrieved one or more product attributes and product sales associated with the product, based on the implementation of non-parametric machine learning (ML) modeling on a data model;
quantify a contribution of each product attribute on the product sales, based on the established relationship and a game theoretic framework, wherein the contribution of each product attribute on the product sales is quantified to determine weights of the respective product attributes; and
estimate demand transferability among the set of products based on the determined weights of the respective product attributes.

20. The non-transitory computer readable medium as claimed in claim 19, wherein the data model is generated based on:
ingestion and storage of raw data associated with the set of products from a plurality of sources;
design and development of metadata for at least one of model versioning, model performance, model output, and action recommendation/simulation; and
building of the data model based on training using the ingested data and the developed metadata.
